(19) United States
(12) Patent Application Publication
(10) Pub. No.: US 2026/0113022 A1
(43) Pub. Date: Apr. 23, 2026

(54) BIAS TEMPERATURE INSTABILITY MITIGATION IN A DELAY CIRCUIT

(71) Applicant: Micron Technology, Inc., Boise, ID (US)

(72) Inventor: Zhi Qi HUANG, Alpharetta, GA (US)

(21) Appl. No.: 19/314,572

(22) Filed: Aug. 29, 2025

Related U.S. Application Data
(60) Provisional application No. 63/708,570, filed on Oct. 17, 2024.

(51) Int. Cl. H03K 5/134; H03K 3/037; H03K 5/00

(52) U.S. Cl. CPC H03K 5/134; H03K 3/037; H03K 2005/00195

(57) ABSTRACT

A delay circuit with bias temperature instability (BTI) mitigation includes an input node; an output node configured to provide a delayed output signal that is a delayed representation of an input signal; a first inverter stage including a first complementary metal-oxide-semiconductor (CMOS) inverter and a resistive-capacitive (RC) delay circuit configured to provide an RC delay for a signal transition of the input signal, wherein the RC delay circuit includes a resistive network of transistors coupled between a first p-channel metal-oxide-semiconductor (PMOS) transistor and a first n-channel metal-oxide-semiconductor (NMOS) transistor of the first CMOS inverter; a second inverter stage including a second CMOS inverter coupled between the first inverter stage and the output node; and a supply cutoff circuit configured to disconnect the resistive network of transistors and/or the second CMOS inverter from respective voltage supplies based on one or more supply cutoff conditions being satisfied.

### CROSS-REFERENCE TO RELATED APPLICATION

This Patent Application claims priority to U.S. Provisional Patent Application No. 63/708,570, filed on October 17, 2024, entitled “BIAS TEMPERATURE INSTABILITY MITIGATION IN A DELAY CIRCUIT,” and assigned to the assignee hereof. The disclosure of the prior Application is considered part of and is incorporated by reference into this Patent Application.

### TECHNICAL FIELD

The present disclosure generally relates to delay circuits with bias temperature instability mitigation.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

A semiconductor device may include a plurality of cascaded connected circuits that may include one or more first conductivity type transistors and/or one or more second conductivity type transistors. For example, a voltage-to-time converter (VTC) may include a plurality of cascaded connected circuits. A VTC, in the context of dynamic random-access memory (DRAM), is a delay circuit that translates a voltage level into a corresponding time delay. For example, the VTC may translate a signal pulse into a delayed signal pulse. VTCs may be used in DRAM circuits for various timing-critical operations, such as sense amplification, refresh control, and clock generation, where precise timing is essential for correct data storage and retrieval.

### BRIEF DESCRIPTION OF THE DRAWINGS

FIG. 1 shows a delay circuit according to one or more implementations.

### DETAILED DESCRIPTION

In DRAM, the precise timing of operations is essential for maintaining high performance and data integrity. Since DRAM operates with very tight timing margins (such as the sense amplifier triggering time during a read), a VTC helps to ensure that the voltage levels that define these operations are correctly translated into the required time intervals. Any drift or inaccuracy in the VTC can lead to incorrect timings, resulting in errors like failed reads, data retention issues, or inefficient refresh cycles.

Bias temperature instability (BTI) is a phenomenon affecting transistors (particularly, metal-oxide-semiconductor field-effect transistors (MOSFETs)), where prolonged exposure to a high bias voltage and temperature conditions causes gradual degradation of the transistor characteristics, which may include a thinning of a gate oxide film. The thinning of the gate oxide film may cause a threshold voltage (Vth) of a transistor to change. BTI degradation may occur in a PMOS transistor when a gate voltage is lower than a source voltage. Thus, a PMOS transistor may be protected from BTI when the gate voltage is equal to or greater than the source voltage. BTI degradation may occur in an NMOS transistor when a gate voltage is higher than a source voltage. Thus, an NMOS transistor may be protected from BTI when the gate voltage is equal to or less than the source voltage.

In a DRAM device, BTI mitigation is crucial because BTI can cause a shift in the threshold voltage of the transistors. The shift in the threshold voltage may affect a timing at which transistors turn on and/or turn off in relation to intended turn-on and turn-off timings. In a VTC, the shift in the threshold voltage of the transistors may cause a shift in delay of one or more functions of the VTC, which may cause unintended delays and affect an accuracy of a delay function of the VTC. Moreover, BTI may cause the threshold voltage to continue to shift over time, with BTI degradation increasing over time. Thus, the accuracy of the delay function of the VTC may degrade over time, degrading a reliability of the VTC and eventually shortening a lifetime of the DRAM device.

Put another way, BTI can affect how accurately the VTC converts an input signal into a delayed output signal. As the threshold voltage of one or more transistors in the VTC drifts, a time delay generated by the VTC can become inaccurate. For instance, if the threshold voltage increases due to BTI, the VTC may take longer to convert a signal pulse into a time-delayed signal pulse, leading to delayed operations in DRAM, and causing performance degradation.

A VTC is sensitive to any drift in transistor behavior because it relies on a precise relationship between voltage and time. Even a slight degradation caused by BTI can lead to a timing mismatch between when data is written or read and when the actual voltage transitions occur in the DRAM cells. Over time, this mismatch can lead to errors such as incorrect data reads or writes, since the internal timing may no longer align with the actual state of the data.

BTI-induced degradation over time can reduce the overall reliability of the VTC, impacting the lifespan and operational accuracy of the DRAM. As DRAM scales to smaller technology nodes, these effects become more pronounced, making it essential to reduce BTI to maintain the performance and accuracy of VTCs in DRAM circuits.

As BTI increases, the VTC may require higher operating voltages to compensate for the threshold voltage shifts, leading to increased power consumption in DRAM. Keeping BTI low helps to maintain low-power operation, which is critical for modern DRAM that operates at lower voltages to save energy.

Some implementations described herein are directed to a delay circuit, such as a VTC, with BTI mitigation functionality. A delay circuit with BTI mitigation functionality includes an input node configured to receive an input signal that is driven between a logic low voltage level and a logic high voltage level; an output node configured to provide a delayed output signal that is a delayed representation of the input signal; a first inverter stage including a first complementary metal-oxide-semiconductor (CMOS) inverter and a resistive-capacitive (RC) delay circuit configured to provide an RC delay for a signal transition of the input signal, wherein the RC delay circuit includes a resistive network of transistors coupled between a first p-channel metal-oxide-semiconductor (PMOS) transistor and a first n-channel metal-oxide-semiconductor (NMOS) transistor of the first CMOS inverter, and wherein the first inverter stage is configured to invert the input signal into a first inverted signal based on the RC delay of the RC delay circuit; a second inverter stage including a second CMOS inverter coupled between the first inverter stage and the output node, wherein the second CMOS inverter includes a second PMOS transistor and a second NMOS transistor; and a supply cutoff circuit configured to disconnect the resistive network of transistors and/or the second CMOS inverter from respective voltage supplies based on one or more supply cutoff conditions being satisfied.

The supply cutoff circuit may ensure that gate voltages of the resistive network of transistors remain equal to or less than source voltages, such that the resistive network of transistors (e.g., a resistive network of NMOS transistors) are protected from BTI. Additionally, or alternatively, the supply cutoff circuit may ensure that a gate voltage of the second PMOS transistor remains equal to or greater than a source voltage of the second PMOS transistor, such that the second PMOS transistor is protected from BTI. Additionally, or alternatively, the supply cutoff circuit may ensure that a gate voltage of the second NMOS transistor remains equal to or less than a source voltage of the second NMOS transistor, such that the second NMOS transistor is protected from BTI. Thus, the supply cutoff circuit may mitigate BTI degradation that could otherwise occur in a transistor when a gate voltage is lower than a source voltage for a PMOS transistor or could otherwise occur in a transistor when a gate voltage is higher than a source voltage for an NMOS transistor. The supply cutoff circuit may improve a reliability of the delay circuit, prolong a life of the delay circuit and a DRAM device associated with the delay circuit, prevent or mitigate errors, and/or reduce power consumption of the delay circuit and a DRAM device associated with the delay circuit.

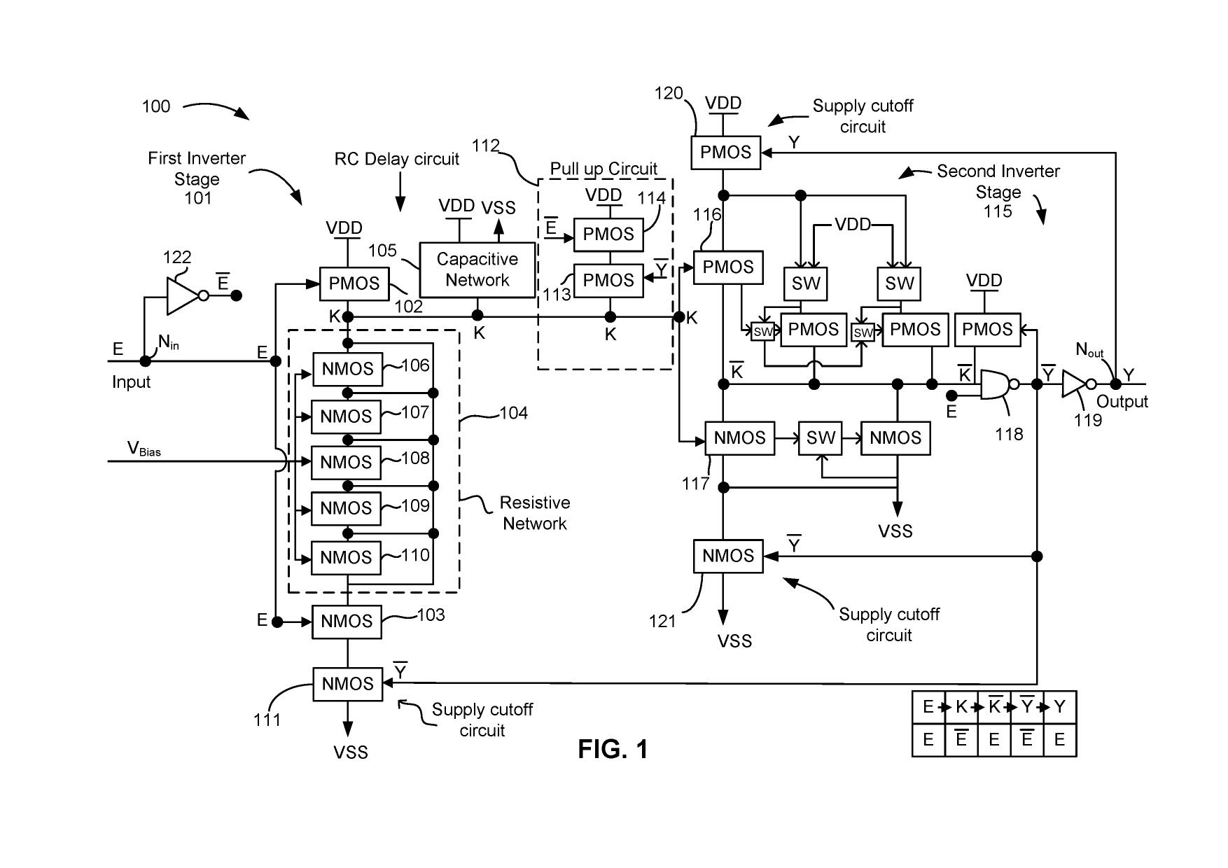

FIG. 1 shows a delay circuit 100 according to one or more implementations. In FIG. 1, transistors may be represented by a simple block, with a gate of a transistor being associated with receiving a control signal (e.g., a gate voltage) represented by an arrow leading into a side of the block. A drain and a source of a transistor may be associated with top and bottom signal lines extending from the block, depending on a conductivity type of the transistor. A drain of an NMOS transistor may be on a top side and a source of an NMOS transistor may be on a bottom side of the block. Conversely, a drain of a PMOS transistor may be on a bottom side and a source of a PMOS transistor may be on a top side of the block.

Additionally, a letter represented with a bar over the letter may be referred to as “letter(bar)” and may be used to denote a signal inversion of a counterpart signal. For example, X(bar) may be a signal inversion of signal X, or vice versa. Thus, as an example, X and X(bar) are inverted counterparts of each other.

The delay circuit 100 may include an input node Nᵢₙ configured to receive an input signal E that is driven between a logic low voltage level and a logic high voltage level, and an output node Nₒᵤₜ configured to provide a delayed output signal Y that is a delayed representation of the input signal E. In some examples, the input signal E may be a VTC command signal that is modulated with command pulses. A positive supply voltage VDD and a negative supply voltage VSS may supply power to the delay circuit 100. Without BTI mitigation, BTI degradation may occur while the input signal E is high. Thus, BTI mitigation may be enabled while the input signal E is high.

The delay circuit 100 may include a first inverter stage 101 that includes a first CMOS inverter, which includes a first PMOS transistor 102 and a first NMOS transistor 103. The first inverter stage 101 may also include a resistive-capacitive (RC) delay circuit configured to provide an RC delay for a signal transition of the input signal E. The RC delay circuit may include a resistive network of transistors 104 and a capacitive network 105 that, in combination, provide an RC time constant associated with the RC delay. The capacitive network 105 may include a capacitive network of transistors or a network of another type of capacitive elements. The first inverter stage 101 may invert the input signal E into a first inverted signal K based on the RC delay of the RC delay circuit. For example, the first CMOS inverter may receive the input signal E at a corresponding input, and invert the input signal E to generate the first inverted signal K at a corresponding output. An amount of time required for the input signal E to be converted into the first inverted signal K may be dictated by the RC delay time.

The resistive network of transistors 104 may be coupled between the first PMOS transistor 102 and the first NMOS transistor 103 of the first CMOS inverter. The resistive network of transistors 104 may include NMOS transistors 106, 107, 108, 109, and 110 that are coupled in series between the first PMOS transistor 102 and the first NMOS transistor 103. A gate of each NMOS transistor 106-110 may receive a bias voltage V_{Bias} as a control voltage. BTI may degrade the NMOS transistors 106-110 such that threshold voltages of the NMOS transistors 106-110 increase. As the threshold voltages of the NMOS transistors 106-110 increase, the RC time constant of the RC delay circuit also increases, which adds additional delay to the first inverter stage 101 and to the delay circuit 100 as a whole. Thus, it is important to mitigate the BTI of the NMOS transistors 106-110.

The delay circuit 100 may include a first supply cutoff circuit 111 coupled between the first CMOS inverter and a negative supply voltage, a pull-up circuit 112 comprising one or more pull-up PMOS transistors, such as transistors 113 and 114, and a second inverter stage 115 that includes a second CMOS inverter coupled between the first inverter stage 101 and the output node Nₒᵤₜ.

The first supply cutoff circuit 111 may be configured to mitigate BTI at the NMOS transistors 106-110 such that the NMOS transistors 106-110 are protected from BTI while one or more supply cutoff conditions are satisfied.

The second CMOS inverter may include a second PMOS transistor 116 and a second NMOS transistor 117. The second CMOS inverter may invert the first inverted signal K into a second inverted signal K(bar). For example, the second CMOS inverter may receive the first inverted signal K at a corresponding input, and invert the first inverted signal K to generate the second inverted signal K(bar) at a corresponding output. The second inverter stage 115 may further include intermediate output component 118 coupled to the corresponding output of the second CMOS inverter, and an output inverter 119. The intermediate output component 118 may be a NAND gate. The second inverter stage 115 may further include additional logic, including switches SW and transistors.

The delay circuit 100 may include a second supply cutoff circuit 120 coupled between the second CMOS inverter and the positive supply voltage VDD, and a third supply cutoff circuit 121 coupled between the second CMOS inverter and the negative supply voltage VSS. The second supply cutoff circuit 120 may be configured to mitigate BTI at the second PMOS transistor 116 such that the second PMOS transistor 116 is protected from BTI while one or more supply cutoff conditions are satisfied. The pull-up circuit 112 may also be used to help mitigate BTI at the second PMOS transistor 116 such that the second PMOS transistor 116 is protected from BTI while one or more BTI mitigation conditions are satisfied. The third supply cutoff circuit 121 may be configured to mitigate BTI at the second NMOS transistor 117 such that the second NMOS transistor 117 is protected from BTI while one or more supply cutoff conditions are satisfied.

The intermediate output component 118 may be configured to provide a first trigger signal Y(bar) that indicates that the RC delay is complete. The first trigger signal Y(bar) may be an inversion of the second inverted signal K(bar). Thus, the first trigger signal Y(bar) may be a third inverted signal. The intermediate output component 118 may receive the second inverted signal K(bar) and the input signal E, and generate the first trigger signal Y(bar) as the third inverted signal based on the second inverted signal K(bar) and the input signal E. The output inverter 119 may invert the first trigger signal Y(bar) (e.g., the third inverted signal) to generate the delayed output signal Y as a fourth inverted signal. Thus, the delayed output signal Y is a non-inverted representation of the input signal E. The signal progression through the delay circuit 100 may be as follows E K K(bar) Y(bar) Y. An equivalent signal progression through the delay circuit 100 in relation to the input signal E may be as follows E E(bar) E E(bar) E. Thus, Y is a delayed representation of E.

The first supply cutoff circuit 111 may receive the first trigger signal (Y)bar, and disconnect the first NMOS transistor 103 and the resistive network of transistors 104 from the negative supply voltage VSS based on the first trigger signal Y(bar) indicating that the RC delay, for a low-to-high signal transition of the input signal E, is complete. In other words, the first supply cutoff circuit 111 may disconnect the first NMOS transistor 103 and the resistive network of transistors 104 from the negative supply voltage VSS based on the input signal E having the logic high voltage level.

The first supply cutoff circuit 111 may be an NMOS transistor having a control gate configured to receive the first trigger signal Y(bar). Thus, the first supply cutoff circuit 111 may disconnect the first NMOS transistor 103 and the resistive network of transistors 104 from the negative supply voltage VSS when the first trigger signal Y(bar) has a logic low voltage level, which may occur when both the second inverted signal K(bar) and the input signal E are both logic high values (e.g., a logic 1). When the second inverted signal K(bar) and the input signal E are both logic high values (e.g., a logic 1), the first trigger signal Y(bar) will be a logic low value (e.g., a logic 0). Thus, the intermediate output component 118 (e.g., a NAND gate) may generate the first trigger signal, as a logic low signal, only when certain conditions are satisfied (e.g., when both the second inverted signal K(bar) and the input signal E are both logic high values), which may only occur when the RC delay, for a low-to-high signal transition of the input signal E, is complete.

Following a low-to-high signal transition of the input signal E, the second inverted signal K(bar) reaches a logic high value at an input of the intermediate output component 118 based on the RC delay being complete. As a result, the first trigger signal Y(bar) will switch to a logic low value based on the RC delay being complete. The first supply cutoff circuit 111 in turn may disconnect the first NMOS transistor 103 and the resistive network of transistors 104 from the negative supply voltage VSS, which ensures that the gate electrodes of the NMOS transistors 106-110 are maintained to be at an equal or higher potential than the source electrodes of the NMOS transistors 106-110, thereby protecting the NMOS transistors 106-110 from BTI.

In addition, the first supply cutoff circuit 111 may disconnect the first NMOS transistor 103 and the resistive network of transistors 104 from the negative supply voltage VSS to disconnect the first NMOS transistor 103 and the resistive network of transistors 104 of transistors from a direct current (DC) leakage path, which may reduce energy consumption and improve reliability of the delay circuit 100. Moreover, the first supply cutoff circuit 111 may disconnect the first NMOS transistor 103 and the resistive network of transistors 104 from the negative supply voltage VSS to reduce a BTI of the resistive network of transistors 104, which may reduce drift of the RC time constant and improve reliability of the delay circuit 100.

As noted above, the pull-up circuit 112 may help mitigate BTI at the second PMOS transistor 116 such that the second PMOS transistor 116 is protected from BTI.

The first pull-up PMOS transistor 113 and the second pull-up PMOS transistor 114 may be coupled in series between the positive supply voltage VDD and a corresponding input of the second CMOS inverter (e.g., the gate electrodes of the second PMOS transistor 116 and the second NMOS transistor 117). The first pull-up PMOS transistor 113 includes a control gate that may receive the first trigger signal Y(bar) from the intermediate output component 118. The first pull-up PMOS transistor 113 may tie the input of the second CMOS inverter to the positive supply voltage VDD based on the first trigger signal Y(bar) indicating that the RC delay, for the low-to-high signal transition of the input signal E, is complete. For example, the first pull-up PMOS transistor 113 may tie the control gate of the second PMOS transistor 116 to the positive supply voltage VDD based on the first trigger signal Y(bar) indicating that the RC delay, for the low-to-high signal transition of the input signal E, is complete, in order to protect the second PMOS transistor 116 from BTI.

In addition, the second pull-up PMOS transistor 114 includes a control gate that may receive an inversion of the input signal E. For example, the control gate of the second pull-up PMOS transistor 114 may receive an inverted signal E(bar) from an inverter 122. The inverter 122 may receive the input signal E and provide the inverted signal E(bar) to the control gate of the second pull-up PMOS transistor 114. The second pull-up PMOS transistor 114 may tie the control gate of the second PMOS transistor 116 to the positive supply voltage VDD, to protect the second PMOS transistor 116 from BTI, based on the input signal E having the logic high voltage level (e.g., based on the signal E(bar) having the logic low voltage level). Thus, the pull-up circuit 112 pulls the control gate of the second PMOS transistor 116 to the positive supply voltage VDD when the input signal E has the logic high voltage level, and when the first trigger signal Y(bar) transitions from a low-to-high signal level, indicating that the RC delay, for the low-to-high signal transition of the input signal E, is complete. The pull-up circuit 112 may ensure that a gate electrode of the second PMOS transistor 116 is maintained to be at an equal or higher potential than a source electrode of the second PMOS transistor 116, thereby protecting the second PMOS transistor 116 from BTI.

As noted above, the second supply cutoff circuit 120 may help mitigate BTI at the second PMOS transistor 116 such that the second PMOS transistor 116 is protected from BTI. The second supply cutoff circuit 120 may receive the delayed output signal Y, and disconnect the second CMOS inverter from the positive supply voltage VDD (e.g., from a positive voltage supply) based on the delayed output signal Y having the logic high voltage level, which occurs when the input signal E is high. Thus, the delayed output signal Y may function as a second trigger signal for the second supply cutoff circuit 120. The second supply cutoff circuit 120 may disconnect the second PMOS transistor 116 from the positive supply voltage VDD, based on the delayed output signal Y having the logic high voltage level, in order to protect the second PMOS transistor 116 from BTI. In some examples, the second supply cutoff circuit 120 is a PMOS transistor having a control gate configured to receive the delayed output signal Y. The pull-up circuit 112 may ensure that a gate electrode of the second PMOS transistor 116 is maintained to be at an equal or higher potential than a source electrode of the second PMOS transistor 116, thereby protecting the second PMOS transistor 116 from BTI.

As noted above, the third supply cutoff circuit 121 may help mitigate BTI at the second NMOS transistor 117 such that the second NMOS transistor 117 is protected from BTI. The third supply cutoff circuit 121 may be configured to receive the first trigger signal Y(bar), and disconnect the second CMOS inverter from the negative supply voltage VSS based on the first trigger signal indicating that the RC delay, for the low-to-high signal transition of the input signal E, is complete. For example, the third supply cutoff circuit 121 may disconnect the second NMOS transistor 117 from the negative supply voltage VSS (e.g., from a negative voltage supply) based on the first trigger signal Y(bar) indicating that the RC delay, for the low-to-high signal transition of the input signal E, is complete. The third supply cutoff circuit 121 may disconnect the second NMOS transistor 117 from the negative supply voltage VSS based on the input signal E having the logic high voltage level. The third supply cutoff circuit 121 may be an NMOS transistor having a control gate configured to receive the first trigger signal Y(bar). Thus, the third supply cutoff circuit 121 may operate in a similar manner to the first supply cutoff circuit 111.

The third supply cutoff circuit 121 may disconnect the second NMOS transistor 117 from the negative supply voltage VSS, to disconnect the second NMOS transistor 117 from a DC leakage path, which may reduce energy consumption and improve reliability of the delay circuit 100. Moreover, the third supply cutoff circuit 121 may disconnect the second NMOS transistor 117 from the negative supply voltage VSS, to reduce a BTI of the second NMOS transistor 117, which may reduce drift of a delay timing of the delay circuit 100 and improve reliability of the delay circuit 100.

In some cases, the first supply cutoff circuit 111, the second supply cutoff circuit 120, the third supply cutoff circuit 121, and/or the pull-up circuit 112 may reduce a drift of the delay timing of the delay circuit 100 from about 160 picoseconds (ps), using no BTI mitigation or using conventional BTI mitigation techniques, to about 20ps or less. Thus, a significant reduction in BTI and delay errors caused by BTI degradation may be realized using the first supply cutoff circuit 111, the second supply cutoff circuit 120, the third supply cutoff circuit 121, and/or the pull-up circuit 112.

The following provides an overview of some Aspects of the present disclosure:

Aspect 1: A delay circuit with BTI mitigation, the delay circuit comprising: an input node configured to receive an input signal that is driven between a logic low voltage level and a logic high voltage level; an output node configured to provide a delayed output signal that is a delayed representation of the input signal; a first inverter stage including a first CMOS inverter and a RC delay circuit configured to provide an RC delay for a signal transition of the input signal, wherein the RC delay circuit includes a resistive network of transistors coupled between a first PMOS transistor and a first NMOS transistor of the first CMOS inverter, and wherein the first inverter stage is configured to invert the input signal into a first inverted signal based on the RC delay of the RC delay circuit; a second inverter stage including a second CMOS inverter coupled between the first inverter stage and the output node, wherein the second CMOS inverter is configured to invert the first inverted signal into a second inverted signal, wherein the second inverter stage includes an intermediate output component coupled to an output of the second CMOS inverter, wherein the intermediate output component is configured to provide a first trigger signal that indicates that the RC delay is complete; and a first supply cutoff circuit coupled between the first CMOS inverter and a negative supply voltage, wherein the first supply cutoff circuit is configured to receive the first trigger signal, and disconnect the first NMOS transistor and the resistive network of transistors from the negative supply voltage based on the first trigger signal indicating that the RC delay, for a low-to-high signal transition of the input signal, is complete.

Aspect 2: The delay circuit of Aspect 1, wherein the first supply cutoff circuit is configured to disconnect the first NMOS transistor and the resistive network of transistors from the negative supply voltage based on the input signal having the logic high voltage level.

Aspect 3: The delay circuit of any of Aspects 1-2, wherein the first supply cutoff circuit is configured to disconnect the first NMOS transistor and the resistive network of transistors from the negative supply voltage to disconnect the first NMOS transistor and the resistive network of transistors from a DC leakage path.

Aspect 4: The delay circuit of any of Aspects 1-3, wherein the first supply cutoff circuit is configured to disconnect the first NMOS transistor and the resistive network of transistors from the negative supply voltage to reduce a BTI of the resistive network of transistors.

Aspect 5: The delay circuit of any of Aspects 1-4, wherein the first supply cutoff circuit is configured to disconnect the first NMOS transistor and the resistive network of transistors from the negative supply voltage to protect the resistive network of transistors from BTI.

Aspect 6: The delay circuit of any of Aspects 1-5, wherein the intermediate output component is a NAND gate configured to receive the second inverted signal and the input signal, and generate the first trigger signal as a third inverted signal based on the second inverted signal and the input signal.

Aspect 7: The delay circuit of Aspect 6, wherein the first supply cutoff circuit is an NMOS transistor having a control gate configured to receive the first trigger signal.

Aspect 8: The delay circuit of Aspect 6, wherein the second inverter stage further includes an output inverter configured to invert the third inverted signal to generate the delayed output signal as a fourth inverted signal, and wherein the delayed output signal is a non-inverted representation of the input signal.

Aspect 9: The delay circuit of any of Aspects 1-8, wherein the input signal is a VTC command signal that is modulated with command pulses.

Aspect 10: The delay circuit of any of Aspects 1-9, further comprising: a pull-up circuit comprising one or more pull-up PMOS transistors, including a first pull-up PMOS transistor, coupled in series between a positive supply voltage and an input of the second CMOS inverter, wherein the first pull-up PMOS transistor includes a control gate configured to receive the first trigger signal, and wherein the first pull-up PMOS transistor is configured to tie the input of the second CMOS inverter to the positive supply voltage based on the first trigger signal indicating that the RC delay, for the low-to-high signal transition of the input signal, is complete.

Aspect 11: The delay circuit of Aspect 10, wherein the second CMOS inverter includes a second PMOS transistor and a second NMOS transistor, wherein the first pull-up PMOS transistor is configured to tie a control gate of the second PMOS transistor to the positive supply voltage based on the first trigger signal indicating that the RC delay, for the low-to-high signal transition of the input signal, is complete, in order to protect the second PMOS transistor from BTI.

Aspect 12: The delay circuit of Aspect 11, wherein the one or more pull-up PMOS transistors include a second pull-up PMOS transistor that includes a control gate configured to receive an inversion of the input signal, and wherein the second pull-up PMOS transistor is configured to tie the control gate of the second PMOS transistor to the positive supply voltage, to protect the second PMOS transistor from BTI, based on the input signal having the logic high voltage level.

Aspect 13: The delay circuit of Aspect 10, wherein the one or more pull-up PMOS transistors include a second pull-up PMOS transistor that includes a control gate configured to receive an inversion of the input signal, and wherein the second pull-up PMOS transistor is configured to tie the input of the second CMOS inverter to the positive supply voltage based on the input signal having the logic high voltage level.

Aspect 14: The delay circuit of any of Aspects 1-13, further comprising: a second supply cutoff circuit coupled between the second CMOS inverter and a positive supply voltage, wherein the second supply cutoff circuit is configured to receive the delayed output signal, and disconnect the second CMOS inverter from the positive supply voltage based on the delayed output signal having the logic high voltage level.

Aspect 15: The delay circuit of Aspect 14, wherein the second CMOS inverter includes a second PMOS transistor and a second NMOS transistor, and wherein the second supply cutoff circuit is configured to disconnect the second PMOS transistor from the positive supply voltage, based on the delayed output signal having the logic high voltage level, in order to protect the second PMOS transistor from BTI.

Aspect 16: The delay circuit of Aspect 14, wherein the second supply cutoff circuit is a PMOS transistor having a control gate configured to receive the delayed output signal.

Aspect 17: The delay circuit of Aspect 14, wherein the intermediate output component is a NAND gate configured to receive the second inverted signal and the input signal, and generate the first trigger signal as a third inverted signal based on the second inverted signal and the input signal, and wherein the second inverter stage further includes an output inverter configured to invert the third inverted signal to generate the delayed output signal as a fourth inverted signal.

Aspect 18: The delay circuit of any of Aspects 1-17, further comprising: a third supply cutoff circuit coupled between the second CMOS inverter and a negative supply voltage, wherein the third supply cutoff circuit is configured to receive the first trigger signal, and disconnect the second CMOS inverter from the negative supply voltage based on the first trigger signal indicating that the RC delay, for the low-to-high signal transition of the input signal, is complete.

Aspect 19: The delay circuit of Aspect 18, wherein the second CMOS inverter includes a second PMOS transistor and a second NMOS transistor, and wherein the third supply cutoff circuit is configured to disconnect the second NMOS transistor from the negative supply voltage based on the first trigger signal indicating that the RC delay, for the low-to-high signal transition of the input signal, is complete.

Aspect 20: The delay circuit of Aspect 19, wherein the third supply cutoff circuit is configured to disconnect the second NMOS transistor from the negative supply voltage based on the input signal having the logic high voltage level.

Aspect 21: The delay circuit of Aspect 19, wherein the third supply cutoff circuit is configured to disconnect the second NMOS transistor from the negative supply voltage to disconnect the second NMOS transistor from a DC leakage path.

Aspect 22: The delay circuit of Aspect 19, wherein the third supply cutoff circuit is configured to disconnect the second NMOS transistor from the negative supply voltage to protect the second NMOS transistor from BTI.

Aspect 23: The delay circuit of Aspect 18, wherein the intermediate output component is a NAND gate configured to receive the second inverted signal and the input signal, and generate the first trigger signal as a third inverted signal based on the second inverted signal and the input signal.

Aspect 24: The delay circuit of Aspect 23, wherein the third supply cutoff circuit is an NMOS transistor having a control gate configured to receive the first trigger signal.

Aspect 25: A delay circuit with BTI mitigation, the delay circuit comprising: an input node configured to receive an input signal that is driven between a logic low voltage level and a logic high voltage level; an output node configured to provide a delayed output signal that is a delayed representation of the input signal; a first inverter stage including a first CMOS inverter and a RC delay circuit configured to provide an RC delay for a signal transition of the input signal, wherein the RC delay circuit includes a resistive network of transistors coupled between a first PMOS transistor and a first NMOS transistor of the first CMOS inverter, and wherein the first inverter stage is configured to invert the input signal into a first inverted signal based on the RC delay of the RC delay circuit; a second inverter stage including a second CMOS inverter coupled between the first inverter stage and the output node, wherein the second CMOS inverter includes a second PMOS transistor and a second NMOS transistor; and a supply cutoff circuit coupled between the second CMOS inverter and a positive supply voltage, wherein the supply cutoff circuit is configured to receive the delayed output signal, and disconnect the second CMOS inverter from the positive supply voltage based on the delayed output signal having the logic high voltage level.

Aspect 26: The delay circuit of Aspect 25, wherein the supply cutoff circuit is configured to disconnect the second PMOS transistor from the positive supply voltage, based on the delayed output signal having the logic high voltage level, in order to protect the second PMOS transistor from BTI.

Aspect 27: The delay circuit of any of Aspects 25-26, wherein the supply cutoff circuit is a PMOS transistor having a control gate configured to receive the delayed output signal.

Aspect 28: The delay circuit of any of Aspects 25-27, wherein the second CMOS inverter is configured to invert the first inverted signal into a second inverted signal, wherein the second inverter stage includes an intermediate output component coupled to an output of the second CMOS inverter, wherein the intermediate output component is configured to provide a third inverted signal that indicates that the RC delay is complete, and wherein the second inverter stage further includes an output inverter configured to invert the third inverted signal to generate the delayed output signal.

Aspect 29: The delay circuit of Aspect 28, wherein the intermediate output component is a NAND gate configured to receive the second inverted signal and the input signal, and generate the third inverted signal based on the second inverted signal and the input signal.

Aspect 30: The delay circuit of Aspect 29, further comprising: a pull-up circuit comprising one or more pull-up PMOS transistors, including a first pull-up PMOS transistor, coupled in series between a positive supply voltage and an input of the second CMOS inverter, wherein the first pull-up PMOS transistor includes a control gate configured to receive the third inverted signal, and wherein the first pull-up PMOS transistor is configured to tie the input of the second CMOS inverter to the positive supply voltage based on the third inverted signal indicating that the RC delay, for a low-to-high signal transition of the input signal, is complete.

Aspect 31: A system configured to perform one or more operations recited in one or more of Aspects 1-30.

Aspect 32: An apparatus comprising means for performing one or more operations recited in one or more of Aspects 1-30.

Aspect 33: A non-transitory computer-readable medium storing a set of instructions, the set of instructions comprising one or more instructions that, when executed by a device, cause the device to perform one or more operations recited in one or more of Aspects 1-30.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A delay circuit with bias temperature instability (BTI) mitigation, the delay circuit comprising:
an input node configured to receive an input signal that is driven between a logic low voltage level and a logic high voltage level;
an output node configured to provide a delayed output signal that is a delayed representation of the input signal;
a first inverter stage including a first complementary metal-oxide-semiconductor (CMOS) inverter and a resistive-capacitive (RC) delay circuit configured to provide an RC delay for a signal transition of the input signal,
wherein the RC delay circuit includes a resistive network of transistors coupled between a first p-channel metal-oxide-semiconductor (PMOS) transistor and a first n-channel metal-oxide-semiconductor (NMOS) transistor of the first CMOS inverter, and
wherein the first inverter stage is configured to invert the input signal into a first inverted signal based on the RC delay of the RC delay circuit;
a second inverter stage including a second CMOS inverter coupled between the first inverter stage and the output node, wherein the second CMOS inverter is configured to invert the first inverted signal into a second inverted signal,
wherein the second inverter stage includes an intermediate output component coupled to an output of the second CMOS inverter, wherein the intermediate output component is configured to provide a first trigger signal that indicates that the RC delay is complete; and
a first supply cutoff circuit coupled between the first CMOS inverter and a negative supply voltage,
wherein the first supply cutoff circuit is configured to receive the first trigger signal, and disconnect the first NMOS transistor and the resistive network of transistors from the negative supply voltage based on the first trigger signal indicating that the RC delay, for a low-to-high signal transition of the input signal, is complete.

2. The delay circuit of claim 1, wherein the first supply cutoff circuit is configured to disconnect the first NMOS transistor and the resistive network of transistors from the negative supply voltage based on the input signal having the logic high voltage level.

3. The delay circuit of claim 1, wherein the first supply cutoff circuit is configured to disconnect the first NMOS transistor and the resistive network of transistors from the negative supply voltage to disconnect the first NMOS transistor and the resistive network of transistors from a direct current (DC) leakage path.

4. The delay circuit of claim 1, wherein the first supply cutoff circuit is configured to disconnect the first NMOS transistor and the resistive network of transistors from the negative supply voltage to protect the resistive network of transistors from BTI.

5. The delay circuit of claim 1, wherein the intermediate output component is a NAND gate configured to receive the second inverted signal and the input signal, and generate the first trigger signal as a third inverted signal based on the second inverted signal and the input signal.

6. The delay circuit of claim 5, wherein the first supply cutoff circuit is an NMOS transistor having a control gate configured to receive the first trigger signal.

7. The delay circuit of claim 5, wherein the second inverter stage further includes an output inverter configured to invert the third inverted signal to generate the delayed output signal as a fourth inverted signal, and
wherein the delayed output signal is a non-inverted representation of the input signal.

8. The delay circuit of claim 1, further comprising:
a pull-up circuit comprising one or more pull-up PMOS transistors, including a first pull-up PMOS transistor, coupled in series between a positive supply voltage and an input of the second CMOS inverter,
wherein the first pull-up PMOS transistor includes a control gate configured to receive the first trigger signal, and
wherein the first pull-up PMOS transistor is configured to tie the input of the second CMOS inverter to the positive supply voltage based on the first trigger signal indicating that the RC delay, for the low-to-high signal transition of the input signal, is complete.

9. The delay circuit of claim 8, wherein the one or more pull-up PMOS transistors include a second pull-up PMOS transistor that includes a control gate configured to receive an inversion of the input signal, and
wherein the second pull-up PMOS transistor is configured to tie the input of the second CMOS inverter to the positive supply voltage based on the input signal having the logic high voltage level.

10. The delay circuit of claim 1, further comprising:
a second supply cutoff circuit coupled between the second CMOS inverter and a positive supply voltage,
wherein the second supply cutoff circuit is configured to receive the delayed output signal, and disconnect the second CMOS inverter from the positive supply voltage based on the delayed output signal having the logic high voltage level.

11. The delay circuit of claim 10, wherein the second CMOS inverter includes a second PMOS transistor and a second NMOS transistor, and
wherein the second supply cutoff circuit is configured to disconnect the second PMOS transistor from the positive supply voltage, based on the delayed output signal having the logic high voltage level, in order to protect the second PMOS transistor from BTI.

12. The delay circuit of claim 10, wherein the second supply cutoff circuit is a PMOS transistor having a control gate configured to receive the delayed output signal.

13. The delay circuit of claim 1, further comprising:
a third supply cutoff circuit coupled between the second CMOS inverter and a negative supply voltage,
wherein the third supply cutoff circuit is configured to receive the first trigger signal, and disconnect the second CMOS inverter from the negative supply voltage based on the first trigger signal indicating that the RC delay, for the low-to-high signal transition of the input signal, is complete.

14. The delay circuit of claim 13, wherein the third supply cutoff circuit is configured to disconnect the second CMOS inverter from the negative supply voltage based on the input signal having the logic high voltage level.

15. The delay circuit of claim 13, wherein the third supply cutoff circuit is an NMOS transistor having a control gate configured to receive the first trigger signal.

16. A delay circuit with bias temperature instability (BTI) mitigation, the delay circuit comprising:
an input node configured to receive an input signal that is driven between a logic low voltage level and a logic high voltage level;
an output node configured to provide a delayed output signal that is a delayed representation of the input signal;
a first inverter stage including a first complementary metal-oxide-semiconductor (CMOS) inverter and a resistive-capacitive (RC) delay circuit configured to provide an RC delay for a signal transition of the input signal,
wherein the RC delay circuit includes a resistive network of transistors coupled between a first p-channel metal-oxide-semiconductor (PMOS) transistor and a first n-channel metal-oxide-semiconductor (NMOS) transistor of the first CMOS inverter, and
wherein the first inverter stage is configured to invert the input signal into a first inverted signal based on the RC delay of the RC delay circuit;
a second inverter stage including a second CMOS inverter coupled between the first inverter stage and the output node, wherein the second CMOS inverter includes a second PMOS transistor and a second NMOS transistor; and
a supply cutoff circuit coupled between the second CMOS inverter and a positive supply voltage,
wherein the supply cutoff circuit is configured to receive the delayed output signal, and disconnect the second CMOS inverter from the positive supply voltage based on the delayed output signal having the logic high voltage level.

17. The delay circuit of claim 16, wherein the supply cutoff circuit is configured to disconnect the second PMOS transistor from the positive supply voltage, based on the delayed output signal having the logic high voltage level, in order to protect the second PMOS transistor from BTI.

18. The delay circuit of claim 16, wherein the supply cutoff circuit is a PMOS transistor having a control gate configured to receive the delayed output signal.

19. The delay circuit of claim 16, wherein the second CMOS inverter is configured to invert the first inverted signal into a second inverted signal, wherein the second inverter stage includes an intermediate output component coupled to an output of the second CMOS inverter,
wherein the intermediate output component is configured to provide a third inverted signal that indicates that the RC delay is complete, and
wherein the second inverter stage further includes an output inverter configured to invert the third inverted signal to generate the delayed output signal.

20. The delay circuit of claim 19, further comprising:
a pull-up circuit comprising one or more pull-up PMOS transistors, including a first pull-up PMOS transistor, coupled in series between a positive supply voltage and an input of the second CMOS inverter,
wherein the first pull-up PMOS transistor includes a control gate configured to receive the third inverted signal, and
wherein the first pull-up PMOS transistor is configured to tie the input of the second CMOS inverter to the positive supply voltage based on the third inverted signal indicating that the RC delay, for a low-to-high signal transition of the input signal, is complete.
